(19) United States
(12) Patent Application Publication
(10) Pub. No.: US 2009/0098291 A1
(43) Pub. Date: Apr. 16, 2009

(54) METHOD OF PRODUCING SOLID SUPPORT FOR BIOLOGICAL ANALYSIS USING PLASTIC MATERIAL

(75) Inventors: Kyu-youn HWANG, Suwon-si (KR); Joon-ho Kim, Seongnam-si (KR); Sung-young Jeong, Yongin-si (KR); Chin-sung Park, Yongin-si (KR)

Correspondence Address: SUGHRUE MION, PLLC, 2100 PENNSYLVANIA AVENUE, N.W., SUITE 800, WASHINGTON, DC, 20037, US

(73) Assignee: Samsung Electronics Co., Ltd., Suwon-si (KR)

(21) Appl. No.: 12/100,700

(22) Filed: Apr. 10, 2008

(30) Foreign Application Priority Data
Oct. 10, 2007 (KR) 10-2007-0102145

(51) Int. Cl. C23C 16/44; B05D 1/36

(52) U.S. Cl. 427/255.28; 427/404

(57) ABSTRACT

The present invention provides a method of manufacturing a solid support for biological analysis using a plastic material, the method including: depositing a metal film on a plastic substrate on which a microstructure is formed; depositing an inorganic oxide on the metal film; and anchoring a compound with an amino functional group or a compound with a water contact angle of 70 to 95 degrees on the inorganic oxide.

### CROSS-REFERENCE TO RELATED PATENT APPLICATION

This application claims the benefit of Korean Patent Application No. 10-2007-0102145, filed on Oct. 10, 2007, in the Korean Intellectual Property Office, the disclosure of which is incorporated herein in its entirety by reference.

### BACKGROUND OF THE INVENTION

1. Field of the Invention

The present invention relates to a method of producing a solid support for use in biological analysis, using a plastic material.

2. Description of the Related Art

In biological analysis, solid supports are used for immobilization of biological samples, separation and purification, and concentration. Conventional solid supports are made from silicon or glass. Such materials can be conveniently processed using conventional photolithographic methods, and easily facilitated to have the reactivity with biological samples by treating the surface of the materials chemically. The surface of silicon or glass can easily be treated with an organosilane. However, silicon and glass are expensive and also require high processing costs.

Plastic, which is a synthetic or semisynthetic polymerization product, can be easily processed to have the various microstructures using such methods as molding and embossing techniques. However, plastics generally have different chemical surface characteristics from silicon or glass, and thus in order to control the surface properties of plastic, a suitable surface treatment method must be used. Such surface treatment methods include photografting, UV irradiation, and plasma treatment. Photografting is a method of radical polymerization wherein, in the presence of a polymerization initiator and monomers, UV radiation is applied onto the plastic. However, in this method, it is difficult to determine the reaction conditions and the rate of reaction depending on the type of plastic. By irradiating UV light on polycarbonate (PC) or polymethylene methacrylate (PMMA), the carboxyl groups therein can be exposed. However, the applicability of this method is very limited (it has been reported that the method can be applied only to the two materials mentioned above), and also the UV irradiation time is considerably long. Another method of plasma treatment may be used for oxidation, followed by a reaction with an organic silane material, but the method can only be applied to a limited number of plastics, and its efficiency is low.

Therefore, a method of efficiently manufacturing a plastic solid support that has affinity to biological substances such as cells, nucleic acids, proteins, and polysaccharides is still in demand.

### SUMMARY OF THE INVENTION

The present invention provides a method of efficiently manufacturing a solid support for biological analysis using a plastic material.

According to an embodiment of the present invention, a method of manufacturing a solid support for biological analysis using a plastic material is provided, the method including depositing a metal film on a plastic substrate with a microstructure formed thereon; depositing an inorganic oxide on the metal film; and anchoring a compound with an amino functional group or a compound with a water contact angle of 70 to 95 degrees on the inorganic oxide, wherein the plastic substrate has a thermal expansion coefficient of 0 to 300 m/mK×10⁻⁶, and the deposition of the inorganic oxide is performed at a temperature of 0 to 50° C.

Another embodiment of the present invention provides a method of manufacturing a solid support for biological analysis using a plastic material including polymerizing a paraxylene compound on a plastic substrate on which a microstructure is formed, wherein the paraxylene compound is a di-paraxylene compound or a paraxylene compound having an amino group, and has a water contact angle of 70 to 95 degrees.

### BRIEF DESCRIPTION OF THE DRAWINGS

The above and other features and advantages of the present invention will become more apparent by describing in detail exemplary embodiments thereof with reference to the attached drawings in which:

FIG. 1 is a scanning electron microscopy (SEM) photographic image illustrating an array structure of polymethylmethacrylate (PMMA) pillars, wherein the length×width×height of each pillar is 23×23×50 μm, and the gap between each of the pillars is 12 μm;

FIG. 2 is a set of photographic images illustrating a result of depositing Cr on PMMA and polydimethylsiloxane (PDMS), followed by deposition of SiO₂;

FIG. 3 is a set of photographic images illustrating water drop patterns on PMMA, PMMA on which Cr/SiO₂ layer is deposited, and PMMA on which Cr/SiO₂/octadecyldimethyl (3-trimethoxysilyl propyl) ammonium (OTC) is deposited;

FIG. 5 is a graph illustrating cell capture efficiencies when a PMMA pillar array chip and a silicon pillar array chip were used in a cell capture process;

FIG. 6 is a graph illustrating polymerase chain reaction (PCR) results when a PMMA pillar array chip and a silicon pillar array chip were used in a cell capture process, cell lysis, and DNA elution;

FIG. 4 is a perspective view of a PMMA chip (A) including a PMMA substrate on which a pillar array is formed, SiO₂ is deposited and then polyethyleneiminetrimethoxysilane (PEIM) is introduced, and a silicon chip (B) including a silicon substrate on which a pillar array is formed and PEIM is introduced;

FIG. 7 is a set of optical microscopy photographic images illustrating E. coli each attached to a naked PMMA substrate (A) (twice repeated), and a PMMA substrate coated with poly(4-aminomethyl-p-xylene) (B) (twice repeated); and

FIG. 8 is a SEM photographic image illustrating a PDMS substrate on which a pillar array is pre-formed and on which poly(4-aminomethyl-p-xylene) is coated.

### DETAILED DESCRIPTION OF THE INVENTION

According to an embodiment of the present invention, a method of manufacturing a solid support for biological analysis using a plastic material is provided, the method including depositing a metal film on a plastic substrate with a microstructure formed thereon; depositing an inorganic oxide on the metal film; and anchoring a compound with an amino functional group or a compound with a water contact angle of 70 to 95 degrees on the inorganic oxide, wherein the plastic substrate has a thermal expansion coefficient of 0 to 300 m/mK×10⁻⁶, and the deposition of the inorganic oxide is performed at a temperature of 0 to 50° C.

The microstructure refers to a structure on a nanometer or a micrometer scale, for example, within a range of 1 nm to 1000 μm. For example, the microstructure may be a pillar structure formed of micropillars, or a grooved structure. In this case, the mean length and height of the cross-sectional area of the pillars and the mean width of the grooves are on a nanometer or a micrometer scale, for example, within a range of 1 nm to 1000 μm.

The method of forming the microstructure on the plastic material may be a well-known method in the art, such as hot embossing or molding, but is not limited thereto. A plastic material is easy to process, and therefore it is easier and less expensive to form a microstructure on a plastic material, compared to forming a microstructure on a silicon, glass or metal substrate. Also, pillars with a high aspect ratio may be formed at low cost using a plastic material. Aspect ratio refers to a ratio of a height of the pillar to a width of the cross-section. The width of the cross-section of the pillar refers to the diameter if the cross sectional shape is a circle, or to the mean width of each side if it is a quadrilateral.

The plastic material used in the embodiments of the present invention may be formed of a polymer having a thermal expansion coefficient of 0 to 300 m/mK×10⁻⁶. If the thermal expansion coefficient is greater than 300 m/mK×10⁻⁶, deposition of the metal film and the inorganic oxide is difficult. Even if deposition is performed, stable deposition is impossible due to a large difference in thermal expansion coefficients between the plastic material and the metal film/inorganic oxide layer, resulting in cracks. The plastic material may include, for example, polymethylmethacrylate (PMMA), polycarbonate (PC), polyimide (PI), cyclo-olefin copolymer (COC), and polyethylene terephthalate (PET), but is not limited thereto. Polystryrene (PS), polyoxymethylene (POM), perfluoroalkoxy copolymer (PFA), polyvinylchloride (PVC), polypropylene (PP), polyether etherketone (PEEK), polyamide (PA), polyvinylidene fluoride (PVDF), polyesteramide (e.g., LCP Vectra™ A950) and epoxy-based polymer (e.g., cross-linked SU-8™), but is not limited thereto. The properties of the above plastic materials as well as silicon are as shown in Table 1.

TABLE 1
Properties of the Main Plastic Materials and Silicon

| | | | | Thermal | |
|---|---|---|---|---|---|
| | | | | expansion | |
| | | | | coefficient | |
| Material | | Tg (° C.) | Tm (° C.) | (ppmK⁻¹) | Structure |
| COC | Cyclo-olefin copolymer | 140 | / | — | Amorphous |
| (TOPASS | | | | | |
| 5013) | | | | | |
| PMMA | polymethymethacrylate | 105 | / | 70-77 | Amorphous |
| PC | Polycarbonate | 150 | / | 66-70 | Amorphous |
| PS | Polystyrene | 100 | / | 30-210 | Amorphous |
| POM | Polyoxymethylene | −15 | 160 | 80-120 | Semi- |
| | | | | | crystalline |
| PFA | perfluoroalkoxy copolymer | — | 310 | — | Semi- |
| | | | | | crystalline |
| PVC | Polyvinyl chloride | 90 | / | 50-180 | Amorphous |
| PP | Polypropylene | −20 | 170 | 100-180 | Semi- |
| | | | | | crystalline |
| PET | Polyethylene terephthalate | 80 | 265 | 20-80 | Semi- |
| | | | | | crystalline |
| PEEK | Polyether etherketone | 150 | 340 | 50-110 | Semi- |
| | | | | | crystalline |
| PA | Polyamide | 50 | 260 | 80-95 | Semi- |
| | | | | | crystalline |
| PVDF | polyvinylidene fluoride | 40 | 210 | 80-140 | semi-crystalline |
| PI | Polyimide | 350 | / | 30-60 | Amorphous |
| LCP Vectra | Liquid crystalline polymer | / | 280 | 0-30 | semi-crystalline |
| A950 | | | | | |
| cross-linked | — | 200 | / | 50 | Amorphous |
| SU-8 | | | | | |
| Silicon | — | / | 1414 | 2.5 | Crystalline |

As used herein, the term “thermal expansion coefficient” refers to a thermodynamic property of a substance given by Incropera, Frank P.; DeWitt, David P. (Aug. 9, 2001). Fundamentals of Heat and Mass Transfer, 5th Edition, Wiley, ISBN 0-471-38650-2. (p. 537). It relates to the change of a material's linear dimensions in response to the change in temperature. It is the fractional change in length per degree of temperature change.

$$α = \frac{1}{Lo} \frac{\partial L}{\partial T}$$

wherein, Lo is the original length, L is the new length, and T is the temperature.

Deposition of the metal film may be performed using vapor-phase deposition, sputtering, or spin coating. The metal may be a material that has a thermal expansion coefficient between that of the plastic material and the inorganic oxide layer, which is able to relieve the thermal expansion coefficient difference between the plastic material and the inorganic oxide layer. For example, the metal may be selected from the group consisting of Cr or Ti.

A metal film is deposited as a intermediate layer between the plastic material and inorganic oxide layer because of the large difference in the thermal expansion coefficient between plastic materials and inorganic oxides such as silicon dioxide. The inorganic oxide is not deposited directly on to the plastic material, and therefore a metal intermediate layer, i.e. a buffer layer, is formed in order to easily deposit inorganic oxides such as silicon dioxide on the plastic material. The thickness of the metal film may be ½ to 1/1000 of the thickness of the inorganic oxide, but is not limited thereto. The thickness of the inorganic oxide may be 100 Å to 100 μm, but is not limited thereto

The method according to the current embodiment of the present invention further includes depositing an inorganic oxide on the metal film, after depositing the metal film. The inorganic oxide may be selected from the group consisting of titanium oxides, chromium oxides, and silicon oxides, but is preferably silicon oxide, and more preferably silicon dioxide. An inorganic oxide such as silicon dioxide may be deposited at a low temperature. For example, the inorganic oxide may be deposited at a temperature of 0 to 50° C., and preferably at room temperature. Inorganic oxides such as silicon dioxide are deposited at a low temperature because plastic may change forms at a high temperature depending the plastic material, and cause an increase in the thermal expansion coefficient difference, resulting in cracks at the interface between the plastic material and the metal film, and between the metal film and metal oxide.

Inorganic oxides, for example, silicon dioxide, may be deposited on the metal layer by a known method such as physical vapor deposition, a sol gel deposition, an e-beam deposition, a dry deposition etc., but not limited thereto.

The solid support with a microstructure coated with the inorganic oxide such as silicon dioxide formed as above may be coupled with a compound that is reactive to biological samples using the properties of the inorganic oxide and used in biological analysis. For example, the solid support with a microstructure pre-coated with silicon dioxide may be coated with a compound with an amino functional group or a compound with a water contact angle of 70 to 95 degrees, and contacted with a microorganism such as bacteria, fungi, and viruses within a pH range of 3 to 6, thereby binding the microorganism to the solid support.

The silicon dioxide layer has a silanol group on its surface. Therefore, the silicon dioxide layer has a superior reactivity with an organosilane, which is useful in activating the substrate as an active functional group. For example, the silicon dioxide layer may be coated with an organosilane compound.

Therefore, the method according to the current embodiment of the present invention includes anchoring a compound with an amino functional group or a compound with a water contact angle of 70 to 95 degrees on the inorganic oxide, after depositing the inorganic oxide.

The compound with an amino functional group or a compound with a water contact angle of 70 to 95 degrees may be an organosilane compound. Anchoring the organosilane on the inorganic oxide may be performed using a well-known method in the art, such as spin coating, deposition, spray coating, or SAM (self-assembled monolayer). The organosilane material may be a material having an alkoxy group or a chloride group which can react with the inorganic oxide layer.

The compound with an amino functional group may be aminosilane. The aminosilane may include 3-aminopropyltriethoxysilane (GAPTES), 3-aminopropyldiethoxysilane (GAPDES), polyethyleneiminetrimethoxysilane (PEIM), N-(3-trimethoxysilyl propyl) ethylenediamine, and N-trimethoxysilylpropyl-N,N,N-chloride trimethylammonium, but is not limited thereto.

The compound with a water contact angle of 70 to 95 degrees may be one or more materials selected from the group consisting of octadecyldimethyl (3-trimethoxysilyl propyl) ammonium (OTC), tridecafluorotetrahydrooctyltrimethoxysilane (DFS), CF₃(CF₂)₃CH₂CH₂SI(OCH₃)₃, CF₃(CF₂)₅CH₂CH₂SI(OCH₃)₃, CF₃(CF₂)₇CH₂CH₂SI(OCH₃)₃, CF₃(CF₂)₉CH₂CH₂SI(OCH₃)₃, (CF₃)₂CF(CF₂)₄CH₂CH₂SI(OCH₃)₃, (CF₃)₂CF(CF₂)₆CH₂CH₂SI(OCH₃)₃, (CF₃)₂CF(CF₂)₈CH₂CH₂SI(OCH₃)₃, CF₃(C₆H₄)C₂H₄Si(OCH₃)₃, CF₃(CF₂)₃(C₆H₄)C₂H₄Si(OCH₃)₃, CF₃(CF₂)₅(C₆H₄)C₂H₄Si(OCH₃)₃, CF₃(CF₂)₇(C₆H₄)C₂H₄Si(OCH₃)₃, CF₃(CF₂)₃CH₂CH₂SiCH₃(OCH₃)₂, CF₃(CF₂)₅CH₂CH₂SiCH₃(OCH₃)₂, CF₃(CF₂)₇CH₂CH₂SiCH₃(OCH₃)₂, CF₃(CF₂)₉CH₂CH₂SiCH₃(OCH₃)₂, (CF₃)₂CF(CF₂)₄CH₂CH₂SiCH₃(OCH₃)₂, (CF₃)₂CF(CF₂)₆CH₂CH₂SiCH₃(OCH₃)₂, (CF₃)₂CF(CF₂)₈CH₂CH₂SiCH₃(OCH₃)₂, CF₃(C₆H₄)C₂H₄SiCH₃(OCH₃)₂, CF₃(CF₂)₃(C₆H₄)C₂H₄SiCH₃(OCH₃)₂, CF₃(CF₂)₅(C₆H₄)C₂H₄SiCH₃(OCH₃)₂, CF₃(CF₂)₇(C₆H₄)C₂H₄SiCH₃(OCH₃)₂, CF₃(CF₂)₃CH₂CH₂Si(OCH₂CH₃)₃, CF₃(CF₂)₅CH₂CH₂Si(OCH₂CH₃)₃, and CF₃(CF₂)₇CH₂CH₂Si(OCH₂CH₃). These compounds may bond to the inorganic oxide using a coating method. For example, OTC or DFS may be SAM-coated on the SiO₂ layer. The water contact angle in the present invention refers to the angle at which water interface meets the solid surface, and is measured by Kruss™ Drop Shape Analysis System type DSA 10 Mk2 (Kruss, Hamburg, Germany), wherein 1.5 μl of a distilled water drop is placed on a sample, and monitored every 0.2 seconds for 10 seconds using a CCD camera, and analyzed using Kruss™ Drop Shape Analysis software (DSA version 1.7, Kruss, Hamburg, Germany). The complete profile of the drop was fitted by the tangent method to a general conic section equation. Both angles from the left and the right are measured. A mean value for each drop is calculated, and a total of 5 drops are measured per sample. The water contact angle is a mean value obtained from the 5 drops.

In the current embodiment of the present invention, the solid support for biological analysis may be used for one or more activities selected from the group consisting of nucleic acid isolation, purification, cell isolation and immobilization.

Another embodiment of the present invention provides a method of manufacturing a solid support for biological analysis using a plastic material including polymerizing a paraxylene compound on a plastic substrate on which a microstructure is formed, wherein the paraxylene compound is a paraxylene compound with an amino group or a paraxylene compound with a water contact angle of 70 to 95 degrees. The paraxylene compound may be a mono-paraxylene or di-paraxylene compound.

Polymerizing the paraxylene compound may be performed by depositing the compound on the plastic material using a method such as chemical vapor deposition (CVD). The deposition process may include vaporizing at 150-180° C. using a vaporizer, producing monomer gas with radicals in a pyrolyzer at 650-700° C., and then depositing the paraxylene compound on the plastic material in a deposition chamber at room temperature, thereby forming a polymer film. When paraxylene compound polymerizes, a type of polyxylene, conventionally called parylene, is produced. When di-p-xylene is heated under partial vacuum, di-radical species are produced, which are polymerized when deposited on the surface. The polymer produced by polymerization of di-p-xylene is also referred to as parylene C. The paraxylene monomer comes into contact with the surface in vapor phase during deposition, capable of approaching all the exposed regions.

The paraxylene compound includes di-p-xylene derivatives, and is preferably a di-p-xylene of Formula 1 below:

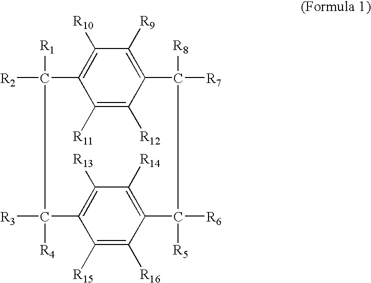

wherein R₁ through R₈ are each independently one of hydrogen, C₁-C₂₀ alkyl, C₆-C₃₀ aryl, C₂-C₂₀ alkenyl, C₂-C₂₀ alkynyl, carboxy, amino, nitro, hydroxyl, and halogen group, and R₉ through R₁₆ are each independently one of hydrogen, halogen, and —NR₁₇R₁₈ group, and R₁₇ and R₁₈ are each independently one of hydrogen or C₁-C₂₀ alkyl group.

Preferably, R₁ through R₈ of Formula 1 of the paraxylene compound are each independently hydrogen or fluoro group, R₉ through R₁₆ are each independently selected from the group consisting of hydrogen, chloro, bromo, fluoro, and —NR₁₇R₁₈ group, and R₁₇ and R₁₈ previously mentioned are each independently hydrogen or C₁-C₅ alkyl group. A specific example of the compound may be selected from the group consisting of di-chloro-di-p-xylene, whose 2 groups in R₁ through R₈ are chloro and the rest are hydrogen and R₉ through R₁₆ are hydrogen; di-p-xylene, whose R₁ through R₁₆ are hydrogen; 4-amino-di-p-xylene; and 4-p-aminomethyl-p-xylene. Di-chloro-di-p-xylene may form polychloro-p-xylene film on the plastic substrate using the deposition process, and di-p-xylene may form a poly-p-xylene film. The polymer film formed as such may have a water contact angle of 70 to 95 degrees. Moreover, because 4-amino-di-p-xylene and 4-aminomethyl-di-p-xylene have amino groups, the amino groups may be introduced to the plastic substrate using the deposition process described above.

The plastic substrate with a microstructure formed thereon and the solid support for biological analysis is as previously described.

According to the current embodiment of the present invention, the solid support for biological analysis may be used for activities selected from the group consisting of nucleic acid isolation, purification, cell isolation and immobilization.

The functional groups introduced by organic silanes and paraxylene compounds may be used for extraction and purification of proteins on the plastic substrate, and therefore be used for devices for analyzing biologics such as Lab-on-a-chip.

According to the method of the present invention, the solid support for biological analysis may be efficiently prepared using a plastic material.

Hereinafter, the present invention will be described more fully with reference to the accompanying Examples, in which exemplary embodiments of the invention are shown. However, the exemplary embodiments are shown as examples, and are not intended to limit the scope of the present invention.

### EXPERIMENTAL EXAMPLE 1

### Preparation of Metal Master for Embossing and Preparation of PMMA Pillar Array

First, a deep reactive ion etching (DRIE) process was performed on a silicon substrate to prepare a pillar array on the silicon substrate. Then, Cr(250 Å)/Cu(250 Å) was deposited on the resultant structure. Nickel electroforming was then performed on the chromium/copper-deposited silicon substrate, and then silicon was removed through wet-etching. Then the edges of the nickel plate prepared using a wire-cutting equipment were cut to complete the manufacture of a nickel master.

The prepared nickel master was mounted on HEX03™ (Jenoptics GmbH, Germany) to carry out an embossing process on polymethylmethacrylate (PMMA). The embossing process was performed at a temperature of 125° C.

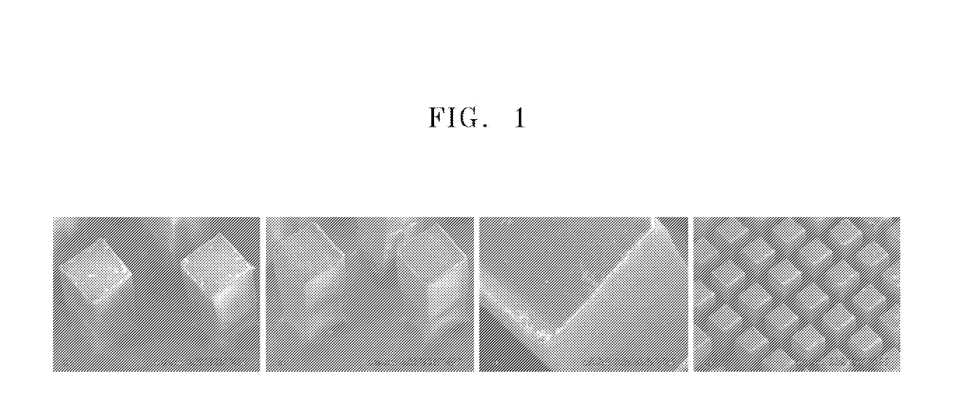

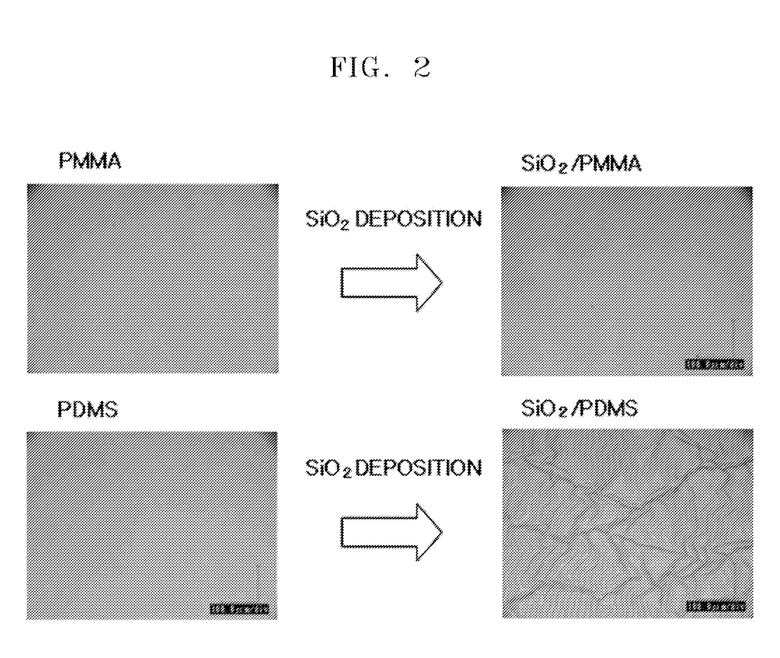

FIG. 1 is an SEM photographic image illustrating an array structure of PMMA pillars formed on a PMMA substrate using a hot embossing process, wherein the length×width×height of each pillar is 23×23×50 μm, and the gap between each of the pillars is 12 μm.

### EXAMPLE 1

### Deposition of SiO₂ on a Plastic Material

In the present example, metal film layers were formed on plastics with different thermal expansion coefficients. Then SiO₂ was deposited on the resultant structures to determine effects according to the thermal expansion coefficients of the plastics.

The plastics used were PMMA and PDMS, which are widely used. PMMA has a thermal expansion coefficient of 70-77×10⁻⁶ mm⁻¹K⁻¹, and PDMS has a thermal expansion coefficient of 310×10⁻⁶ mm⁻¹K⁻¹.

Cr was deposited on each of the PMMA and PDMS substrates using sputtering, to a thickness of 200 to 250 Å. Next, SiO₂ granules were deposited by physical vapor deposition (PVD) on the Cr layer to a thickness of 5000 Å at room temperature.

FIG. 2 is a set of photographic images illustrating a result of depositing Cr on PMMA and PDMS, followed by deposition of SiO₂. Referring to FIG. 2, PDMS with a thermal expansion coefficient of 310 had a crack, thereby resulting in a defective SiO₂ deposition.

### EXAMPLE 2

### Introduction of an Organic Silane on PMMA with Deposited SiO₂.

In the present example, it was determined whether an organosilane could be introduced to the PMMA substrate with deposited SiO₂.

Octadecyldimethyl(3-trimethoxysilyl propyl) ammonium chloride (OTC), an organic silane, was coated on the PMMA substrate with deposited SiO₂ prepared in Example 1, using a SAM-coating method at room temperature. Next, a water contact angle was measured to confirm the coating. The water contact angle was measured by observing with the naked eye or a suitable measuring device.

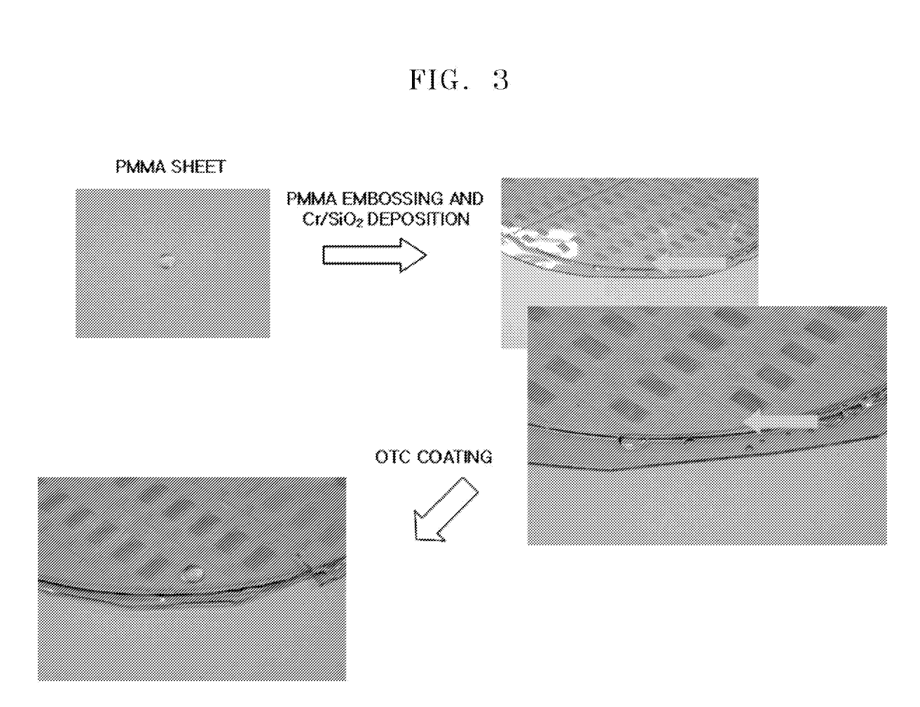

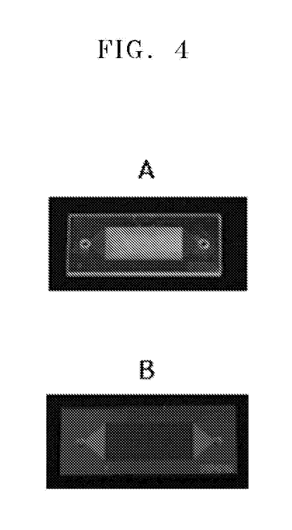

FIG. 3 is a set of photographic images illustrating water drop patterns on PMMA, PMMA on which Cr/SiO₂ is deposited, and PMMA on which Cr/SiO₂/OTC is deposited. It can be seen in FIG. 3 that the PMMA substrate becomes hydrophilic by the introduction of Cr/SiO₂ (water contact angle <10 degrees), and the water contact angle increases to more than 70 degrees by the introduction of the OTC layer. That is, by introducing Cr/SiO₂ to the PMMA substrate, the OTC layer, an organic silane layer can be easily introduced to the PMMA substrate.

### EXAMPLE 3

### Isolation of DNA using PMMA Chip with a Pillar Array Structure Coated with Cr/SiO₂/PEIM Layer

In the present example, trimethoxysilylpropylpolyethyleneimine (PEIM), an organosilane was coated on the PMMA substrate with deposited SiO₂ prepared in Example 1, using the SAM-coating method at room temperature. The prepared PMMA substrate with the Cr/SiO₂/PEIM-coated layer constituting a bottom plate and a PMMA substrate alone constituting a top plate were affixed together to manufacture a PMMA chip (experimental group) including an inlet, an outlet, and a reaction chamber with a capacity of 2.5 μl. The internal surface of the bottom plate of the chamber was formed of PEIM.

As a control group chip, an organosilane, PEIM, was coated on a silicon substrate with a pillar array formed thereon by etching the silicon substrate using a DRIE process, by using a SAM-coating method. The silicon substrate on which the pillar array was formed and the PEIM was coated constituting a bottom plate and a glass substrate alone constituting a top plate were affixed together to manufacture a silicon chip including an inlet, an outlet, and a reaction chamber with a capacity of 2.5 μl. The internal surface of the bottom plate of the chamber was formed of PEIM. The experimental group and the control group chips were formed to have the same pillar array characteristics.

FIG. 4 is a perspective view of a PMMA chip (A) including a PMMA substrate on which SiO₂ is deposited and PEIM is introduced, and a silicon chip (B) including a silicon substrate on which a pillar array is formed and PEIM is introduced.

Urine samples with E. coli were applied to the experimental and the control group chips prepared as above, so that E. coli cells were bound to the internal surface of the chips. The E. coli cells were then lysed and the DNA was bound to the internal surface of the chips and extracted, and PCR was performed on the extracted DNA as a template.

Specifically, urine samples were mixed and diluted each with equal volume of 100 mM sodium acetate (pH 4), and E. coli was injected into the diluent solution to obtain a final concentration of 10⁷ cells/ml (Also known as E. coli spiking). 200 μl of the E. coli-spiked sample was injected into the inlet at a flow rate of 200 μl/min, and then was discharged through the outlet. The cells bound to the PMMA substrate were washed by flowing 200 μl of 100 mM sodium acetate (pH 4) onto the PMMA substrates. In order to calculate the concentration of the cells not bound to the PMMA substrate and existing in the eluate, the eluate was inoculated on a flat medium, cultured, and the E. coli colonies were counted. Based on the number of E. coli in the eluate obtained as above, the efficiency of the E. coli bound to the PMMA substrate, i.e. cell capture efficiency was calculated.

Next, 5 μl of 0.01N NaOH was injected to lyse the cells bound to the PMMA substrate, and the DNA was isolated and recovered by injecting an additional 45 μl of 0.01N NaOH. Taking the DNA included in the eluted solution as a template, and the oligonucleotides of SEQ ID NOS: 1 and 2 (Forward: 5′-YCCAKACTCCTACGGGAGGC-3′, Reverse: 5′-GTATTACCGCRRCTGCTGGCAC-3′) as primers, real-time PCR was performed using a Lightcycle™ (Roche Inc.) apparatus. The PCR conditions were as follows: 95° C. denaturation 5 sec, 62° C. annealing 10 sec, 72° C. elongation 15 sec, for 40 cycles.

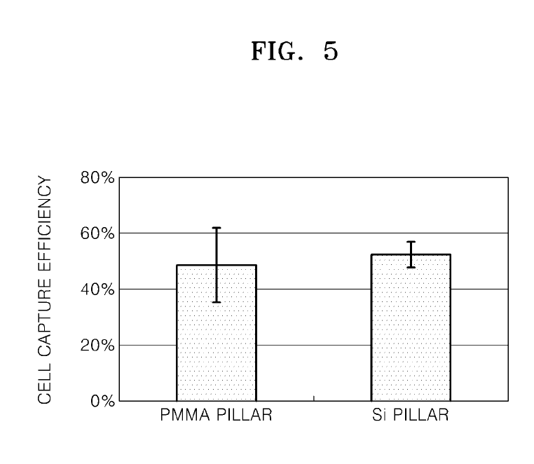

FIG. 5 is a graph illustrating cell capture efficiencies when a PMMA pillar array chip and a silicon pillar array chip were used in the cell capturing process. Referring to FIG. 5, the cell capture efficiencies of the PMMA pillar array chip and the silicon pillar array chip were approximately 48% and 52% respectively, showing that using a plastic such as PMMA produces similar effects as silicon.

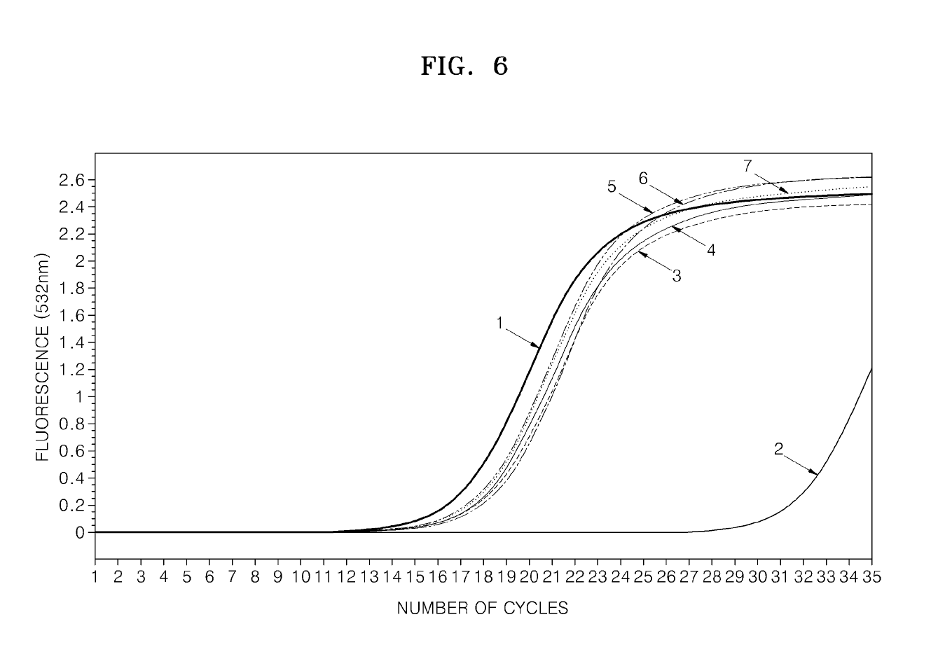

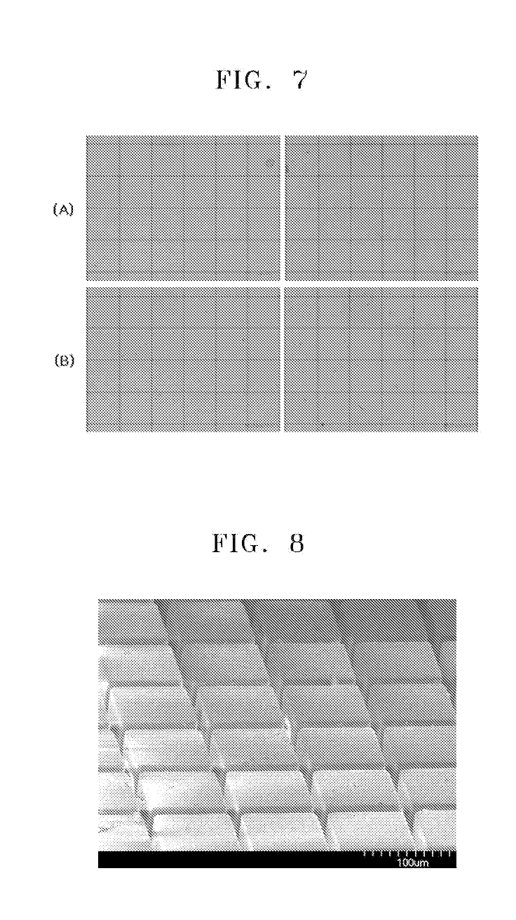

FIG. 6 is a graph illustrating PCR results when a PMMA pillar array chip and a silicon pillar array chip were used in the cell capturing process. Referring to FIG. 6, the Cp values for the PMMA pillar array chip and the silicon pillar array chip were approximately the same at 17.0 and 16.6 respectively, and with positive control of 15.3. In FIG. 6, curves 3 and 4 correspond to the silicon chip, and curves 5, 6, and 7 correspond to PMMA chip, and curves 1 and 2 each correspond to positive and negative controls. The positive control is a sample prepared by adding 200 μl of E. coli into an Eppendorf tube, precipitating by centrifuging at 12000 rpm, washing the precipitant with 200 μl of sodium acetate buffer and precipitating again by centrifuging, and extracting the DNA by lysing the cells with 50 μl of 0.01N NaOH. The negative control is a sample without any DNA added to the PCR mix. Here, Cp value is a PCR cycle threshold, taking the point when a second-derivative value of the fluorescent intensity curve is 0.

### EXAMPLE 4

### Coating of Paraxylene Material on the PMMA Substrate

In the present example, 4-aminomethyl-di-p-xylene was coated repeatedly on a flat PMMA substrate to a thickness of 5 μm. 4-aminomethyl-di-p-xylene was vaporized at 180° C. using a CVD coater, hydrolyzed at 650° C., and deposited on PMMA at room temperature. The PMMA substrate was cut into a size of 25.4 mm×25.4 mm, then a sample including bacterial cells was added to the surface of the PMMA coated with the poly(4-aminomethyl-p-xylene) material to observe an increase in the cell adhesion level compared to the substrate without coating. The observation was performed with an optical microscope (3000-fold magnification), and the adhered bacteria were counted.

10 μl of 1.0 OD E. coli suspended in 1×PBS (pH 7.0) was added into 990 μl of sodium acetate buffer (pH 3.0, 100 mM) to prepare a 0.01 OD E. coli sample. The sample was placed on a patched plastic substrate, left for 5 minutes, and washed for 2 minutes with sodium acetate buffer and the adhered bacteria were counted.

FIG. 7 is a set of optical microscopy photographic images illustrating E. coli attached to a naked PMMA substrate (A) (repeated twice), and a PMMA substrate coated with poly(4-aminomethyl-p-xylene) (B) (repeated twice). Referring to FIG. 7, the number of bacteria bound to the paraxylene-coated substrate (average of 55 colonies) increased at least 10-fold compared to the number of bacteria bound to the substrate without coating (3 colonies).

### EXAMPLE 5

### Preparation of SU-8 Master and Paraxylene-Coated Substrate for Preparing PDMS Pillar Array.

An SU-8 mold having a pillar array was prepared using SU-8 2050™ (Microchem) following the process provided in the manual by Microchem. The length×width×height of each of the pillars was 100×100 ×50 μm, and the gap between each of the pillars was 12 μm. Using the prepared SU-8™ mold, pillar array was fabricated on PDMS (Silgard™ 184, Dow corning Co.) by conventional PDMS molding process. The PDMS substrate on which the pillar array was formed was coated with poly(4-aminomethyl-p-xylene) under the same coating conditions as Example 4.

FIG. 8 is a SEM photographic image illustrating a PDMS substrate on which poly(4-aminomethyl-p-xylene) is coated and on which a pillar array is formed. Referring to FIG. 8, it can be seen with the naked eye that poly(4-aminomethyl-p-xylene can be directly coated on the PDMS substrate on which the pillar array is coated.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of manufacturing a solid support for biological analysis, the method comprising:
depositing a metal film on a plastic substrate, the plastic substrate being provide with a microstructure formed thereon;
depositing an inorganic oxide on the metal film; and
anchoring a compound with an amino functional group or a compound with a water contact angle of 70 to 95 degrees on the inorganic oxide, wherein the plastic substrate has a thermal expansion coefficient of 0 to 300 m/mK×10⁻⁶, and the deposition of the inorganic oxide is performed at a temperature of 0 to 50° C.

2. The method of claim 1, wherein the microstructure comprises micropillars.

3. The method of claim 1, wherein the metal is selected from the group consisting of Cr and Ti.

4. The method of claim 1, wherein the plastic is selected from the group consisting of polymethylmethacrylate, polycarbonate, polyimide, cyclo-olefin copolymer, and polyethylene terephthalate.

5. The method of claim 1, wherein the inorganic oxide is selected from the group consisting of silicon oxide, titanium oxide, and chromium oxide.

6. The method of claim 1, wherein the compound with the amino functional group is aminosilane.

7. The method of claim 6, wherein the aminosilane is selected from the group consisting of 3-aminopropyltriethoxysilane, 3-aminopropyldiethoxysilane, polyethyleneiminetrimethoxysilane, N-(3-trimethoxysily propyl) ethylenediamine, and N-trimethoxysilylpropy-N,N,N-chloride trimethylammonium.

8. The method of claim 1, wherein the compound with the water contact angle of 70 to 95 degrees is selected from the group consisting of octadecyldimethyl (3-trimethoxysilyl propyl) ammonium, tridecafluorotetrahydrooctyltrimethoxy-silane, CF₃(CF₂)₃CH₂CH₂SI(OCH₃)₃, CF₃(CF₂)₅CH₂CH₂SI(OCH₃)₃, CF₃(CF₂)₇CH₂CH₂SI(OCH₃)₃, CF₃(CF₂)₉CH₂CH₂SI(OCH₃)₃, (CF₃)₂CF(CF₂)₄CH₂CH₂SI(OCH₃)₃, (CF₃)₂CF(CF₂)₆CH₂CH₂SI(OCH₃)₃, (CF₃)₂CF(CF₂)₈CH₂CH₂SI(OCH₃)₃, CF₃(C₆H₄)C₂H₄Si(OCH₃)₃, CF₃(CF₂)₃(C₆H₄)C₂H₄Si(OCH₃)₃, CF₃(CF₂)₅(C₆H₄)C₂H₄Si(OCH₃)₃, CF₃(CF₂)₇(C₆H₄)C₂H₄Si(OCH₃)₃, CF₃(CF₂)₃CH₂CH₂SiCH₃(OCH₃)₂, CF₃(CF₂)₅CH₂CH₂SiCH₃(OCH₃)₂, CF₃(CF₂)₇CH₂CH₂SiCH₃(OCH₃)₂, CF₃(CF₂)₉CH₂CH₂SiCH₃(OCH₃)₂, (CF₃)₂CF(CF₂)₄CH₂CH₂SiCH₃(OCH₃)₂, (CF₃)₂CF(CF₂)₆CH₂CH₂SiCH₃(OCH₃)₂, (CF₃)₂CF(CF₂)sCH₂CH₂SiCH₃(OCH₃)₂, CF₃(C₆H₄)C₂H₄SiCH₃(OCH₃)₂, CF₃(CF₂)₃(C₆H₄)C₂H₄SiCH₃(OCH₃)₂, CF₃(CF₂)₅(C₆H₄)C₂H₄SiCH₃(OCH₃)₂, CF₃(CF₂)₇(C₆H₄)C₂H₄SiCH₃(OCH₃)₂, CF₃(CF₂)₃CH₂CH₂Si(OCH₂CH₃)₃, CF₃(CF₂)₅CH₂CH₂Si(OCH₂CH₃)₃, and CF₃(CF₂)₇CH₂CH₂Si(OCH₂CH₃).

9. The method of claim 1, wherein the biological analysis is a separation of microorganisms or nucleic acids.

10. A method of manufacturing a solid support for biological analysis using a plastic material, the method comprising polymerizing a paraxylene compound on a plastic substrate, wherein the plastic substrate is provided with a microstructure formed thereon; and wherein the paraxylene compound is a paraxylene compound with an amino group, or a paraxylene compound with a water contact angle of 70 to 95 degrees.

11. A method of claim 10, wherein the paraxylene compound is a compound of Formula 1 below: 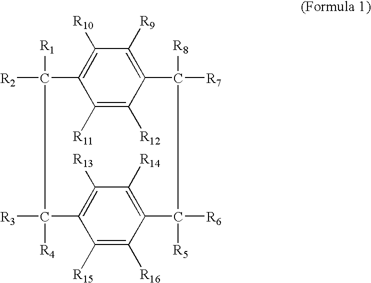
wherein R₁ through R₈ are each independently selected from the group consisting of hydrogen, C₁-C₂₀ alkyl, C₆-C₃₀ aryl, C₂-C₂₀ alkenyl, C₂-C₂₀ alkynyl, carboxy, amino, nitro, hydroxyl, and halogen group, and R₉ through R₁₆ are each independently selected from the group consisting of hydrogen, halogen, and —NR₁₇R₁₈ group, and R₁₇ and R₁₈ are each independently one of hydrogen or C₂-C₂₀ alkyl group.

12. The method of claim 11, wherein, in Formula 1 of the paraxylene compound, R₁ through R₈ are each independently one of hydrogen or fluoro group, R₉ through R₁₆ are each independently selected from the group consisting of hydrogen, chloro, bromo, fluoro, and NR₁₇R₁₈ group, and R₁₇ and R₁₈ are each independently one of hydrogen or C₁-C₅ alkyl group.

13. The method of claim 10, wherein polymerizing the paraxylene compound comprises chemical vapor depositing the paraxylene compound on the plastic substrate.

14. The method of claim 10, wherein the biological analysis is an isolation of microorganisms or nucleic acids.


SEQUENCE LISTING (2 sequences)

SEQ ID NO: 1 - DNA, 20 bp, Artificial Sequence
  forward primer
yccakactcctacgggaggc

SEQ ID NO: 2 - DNA, 22 bp, Artificial Sequence
  reverse primer
gtattaccgcrrctgctggcac